(19) United States
(12) Patent Application Publication
(10) Pub. No.: US 2005/0058007 A1
(43) Pub. Date: Mar. 17, 2005

(54) Method for testing a circuit unit to be tested, and a test apparatus

(76) Inventors: Erwin Thalmann, Villach (AT); Manfred Moser, Dachau (DE)

Correspondence Address: JENKINS & WILSON, PA, 3100 TOWER BLVD, SUITE 1400, DURHAM, NC, 27707, US

(21) Appl. No.: 10/916,909

(22) Filed: Aug. 12, 2004

(30) Foreign Application Priority Data
Aug. 22, 2003 (DE) 10338677.7

(51) Int. Cl. G01R 31/02

(52) U.S. Cl. 365/232

(57) ABSTRACT

The invention provides a test apparatus for testing a circuit unit (113) to be tested which has a data input unit (104) for supplying a nominal data signal (117) to the circuit unit (113) to be tested, and a driver unit (108) for driving the actual data signal (105) (which is emitted from the circuit unit (113) to be tested as a function of the nominal data signal (117) supplied to it) to a data output unit (109) with at least one further signal, by means of which the serviceability of the circuit unit (113) to be tested can be determined being diverted to the data output unit (109).

The present invention relates in general to test apparatuses for testing circuit units to be tested, and relates in particular to a test apparatus for testing a circuit unit to be tested in a circuit arrangement, which tests circuit units for their serviceability by means of test modes which can be specifically predetermined.

Testing of newly developed circuit units is becoming increasingly important, since new memory architectures such as memory architectures based on double the data rate (DDR) are becoming increasingly important for memory modules.

Particularly in the case of memory architectures based on writing and reading data to and from memory modules at double the data rate, additional data signals are provided for synchronization.

For this reason it is important that, in addition to an actual data stream which is emitted from circuit units to be tested, a further signal, for example a synchronization signal, is also tested, in order to obtain a reliable statement about the serviceability of the circuit unit to be tested.

During manufacture of circuit units, these units are normally tested for their serviceability by automatic test equipment (ATE). In this case it is necessary to improve the parallelity of the tested circuit units in the automatic test equipment, in order to reduce the test costs. For example, in the case of an automatic test which is associated with the manufacture of circuit units, only four DDR modules are normally tested in parallel (by means of a “touch down”), in which case all the data signals should be detected at the same time. The number of circuit units to be tested is thus restricted by the number of tester channels.

FIG. 2 shows a block diagram of a part of a conventional test apparatus. Data to be tested is read from the circuit unit to be tested and is entered in a driver. Once the data has been driven, it is emitted as a DQ signal and may, for example, be compared with nominal data that has been produced.

Since the circuit unit to be tested, in the case of the DDR method by way of example, has a generator for production of the synchronization signal, this synchronization signal (DQS signal) must also be tested. A line is thus provided from the DQS generator to the driver, so that the driver can emit a DQS signal.

Since only parallelity with regard to testing of the DQ signals can be improved by means of existing automatic test equipment, the DQS signal is disadvantageously not tested at the moment. However, more stringent requirements for testing of circuit units to be tested also in particular require testing of the DQS signal.

In the case of future circuit units to be tested, it will also be possible for further signals to be tested while maintaining a high degree of parallelity. Until now, the testing of circuit units to be tested has been improved by adopting the approach of first of all testing some of the circuit units on a specific analysis connecting device with all of the connections, in which case only four circuit units can be tested per “touch down”. This has then been used for derivation that, if all of the parameters relating to the DQS signal satisfy a module specification, these parameters are then also used in large-scale production.

However, one disadvantage of the known test methods is that they do not allow reliable testing of the circuit unit to be tested, in particular of the DQS pin and of the DQS-relevant parameters. Furthermore the DQS pin and the DQS-relevant parameters are not tested for their functionality during a module test in production.

Since the test channels in an item of test equipment are restricted, it is impossible with known test methods to completely test circuit units to be tested with a high degree of reliability and a high degree of parallelity.

Document DE 100 34 899 C1 discloses a system for testing fast synchronous semiconductor circuits wherein the system provides a simplification of an interface towards the circuit unit to be tested and other components in a way that the functions may be implemented on a single semiconductor chip and that the currently conventional cost efficient apparatuses for production tests may be further employed.

Disadvantageously no increase in parallelity is achieved by the test system according to the DE 100 34 899 C1. Hence, the testing costs are increased due to the low amount of circuit units to be tested which can be tested in parallel.

Document DE 100 34 855 A1 discloses a system for testing fast integrated digital circuits, in particular semiconductor memory devices. This test system enables a test of fast integrated digital circuits having a high data throughput, however additional signals that are let away from the circuit units to be tested cannot be tested with a high parallelity in the test system. Inappropriately the high parallelity of this system can only be used completely if no additional signals that determine the serviceability of the circuit unit to be tested to be tested need to be tested.

A method for on-chip testing of memory cells of integrated memory circuits is described in DE 101 35 966 A1. The disclosed method for testing works on the basis of a plurality of data patterns which may be accessed directly at any time without inverting or recharging. By providing a complex data word register having two different sections a certain increase and the velocity of a test run is achieved, however the disclosed method has the disadvantage that further signals, with which the serviceability of the circuit unit to be tested may be determined, cannot be diverted to a data output unit.

One object of the present invention is thus to provide a test apparatus in which all of the signals which are emitted from the circuit unit to be tested can be tested with a high degree of parallelity.

According to the invention this object is achieved by a test-apparatus having the features of Patent claim 1.

The object is also achieved by a method as specified in Patent claim 9. Further refinements of the invention can be found in the dependent claims.

One major idea of the invention is that, in addition, signals which are to be tested and are emitted from the circuit unit to be tested as a function of a test mode, for example, be diverted to a data output unit, which is provided for the emission of an actual data signal.

According to the invention, a diversion unit is provided for this purpose for diversion of at least one further signal, by means of which the serviceability of the circuit unit to be tested can also be determined, to the data output unit.

One major advantage of the present invention is thus that a synchronization signal can be diverted to a DQ connecting pin (DQ pin). Diversion directly upstream of a d-river unit for driving the test signals is advantageous. The diversion and switching are preferably controlled in the diversion unit by means of a test mode.

A further advantage of the test apparatus according to the invention is that it allows the provision of a DQS connecting pin (DQS pin) on a restricted production appliance. It is also expedient that it is still possible to use a test procedure that is used in conventional test apparatuses.

A further advantage is that the diversion of signals according to the invention can be provided not only for synchronization signals, but for virtually any desired signals. The test apparatus according to the invention thus provides an improvement in parallelity during testing of circuit units to be tested.

The test apparatus according to the invention for testing a circuit unit to be tested in a circuit arrangement essentially has:

a data input unit for supplying a nominal data signal to the circuit unit to be tested, and a driver unit for driving the actual data signal (which is emitted from the circuit unit to be tested as a function of the nominal data signal supplied to it) to a data output unit, in which case the actual data signal is emitted to a data output unit; the serviceability of the circuit unit to be tested can then be determined by means of the actual data signal which is emitted to the data output unit. The test apparatus for testing the circuit unit to be tested also has a diversion unit for diversion of at least one further signal, by means of which the serviceability of the circuit unit to be tested can further be determined, to the data output unit.

Furthermore, the method according to the invention for testing the circuit unit to be tested in a circuit arrangement essentially has the following steps:
a) supply of a nominal data signal to the circuit unit to be tested via a data input unit;
b) supply of the actual data signal which is emitted from the circuit unit to be tested as a function of the nominal data signal that is supplied, to a driver unit; and
c) driving the actual data signal which has been supplied to a data output unit by means of the driver unit with the serviceability of the circuit unit to be tested being determined by the actual data signal which is emitted to the data output unit, in which case diversion of an at least one further signal, by means of which the serviceability of the circuit unit to be tested can be further determined, to the data output unit by means of a diversion unit, with the serviceability of the circuit unit to be tested furthermore being determined by means of the further signal which is emitted to the data output unit.

Advantageous developments and improvements of the respective subject matter of the invention can be found in the dependent claims.

According to one preferred development of the present invention, the diversion unit is in the form of an electronic or mechanical changeover switch. According to a further preferred development of the present invention, the circuit arrangement has a test mode input unit, via which the diversion unit is supplied with a test mode signal.

The test mode signal is advantageously at the same time provided to the circuit unit to be tested in order to carry out a test mode. According to yet another preferred development of the present invention, the circuit arrangement has a system interface which includes a data bus for interchanging data with the circuit unit to be tested, an address bus for addressing data which is stored in the circuit unit to be tested, and a control bus for controlling the interchange of data with the circuit unit to be tested.

According to yet another preferred development of the present invention, the circuit unit to be tested has a synchronization signal production unit, by means of which the further signal, with which the serviceability of the circuit unit to be tested can further be determined is produced.

According to yet another preferred development of the present invention, the further signal with which the serviceability of the circuit unit to be tested can be determined, and which is produced by a synchronization signal production unit for the circuit unit to be tested is a synchronization signal for the circuit unit to be tested.

According to yet another preferred development of the present invention, a data output signal which is emitted from the data output unit, comprises the actual data signal and the further signal.

According to yet another preferred development of the present invention, a connecting device is provided between the diversion unit and the driver unit, via which the actual data signal and the further signal are passed.

The further signal by means of which the serviceability of the circuit unit to be tested is further determined is advantageously defined by the synchronization signal production unit in the circuit unit to be tested, with the further signal being in the form of a synchronization signal.

According to yet another preferred development of the present invention, the circuit unit to be tested is tested in accordance with a test mode which can be predetermined and which is supplied to the circuit arrangement in the form of a test mode signal.

According to yet another preferred development of the present invention, the diversion by means of the diversion unit is provided in accordance with the test mode which can be predetermined and is supplied to the circuit arrangement as a test mode signal.

Furthermore, in one exemplary embodiment of the present invention, it is advantageous for the circuit unit to be tested to be supplied with the nominal data signal via a data bus, which is provided for interchanging data between external circuit units and the circuit unit to be tested.

Exemplary embodiments of the invention will be explained in more detail in the following description and are illustrated in the drawings, in which:

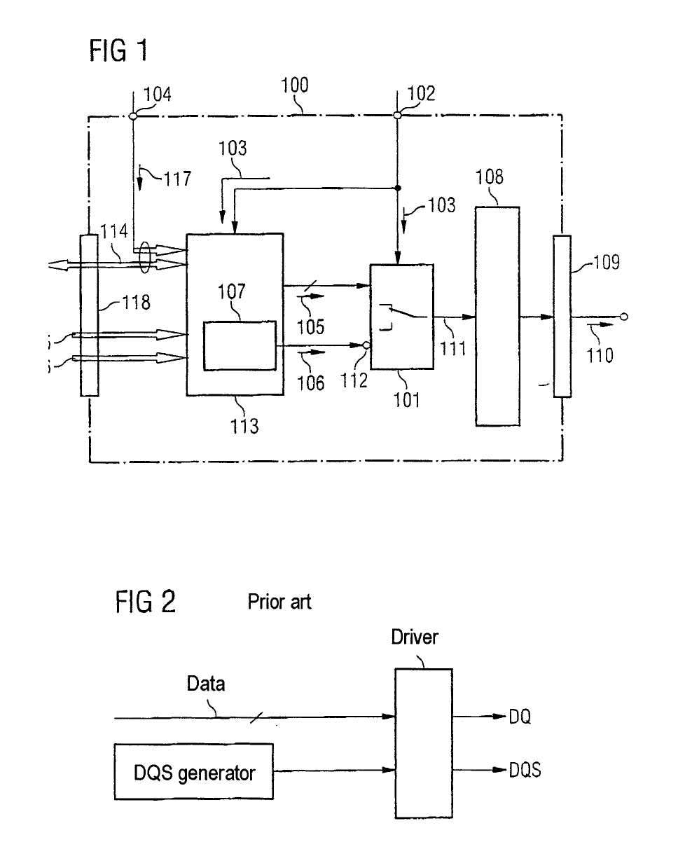

FIG. 1 shows a block diagram of a test apparatus for testing a circuit unit to be tested in a circuit arrangement according to one preferred exemplary embodiment of the present invention; and

FIG. 2 shows a block diagram of a conventional test apparatus.

Identical reference symbols denote identical or functionally identical components or steps in the figures.

In the block diagram shown in FIG. 1 and based on one exemplary embodiment of the present invention, a reference symbol 113 denotes a circuit unit to be tested. The circuit unit to be tested is connected to external circuit units of the test apparatus via a system interface 118.

This system interface 118 comprises a data bus 114 for interchanging data with the circuit unit 113 to be tested, an address bus 115 for addressing data which is stored in the circuit unit to be tested, and a control bus 116 for controlling the interchange of data with the circuit unit 113 to be tested.

It should be mentioned that the reference symbol 100 denotes a circuit arrangement which comprises not only the circuit unit 113 to be tested but also further components which are used for testing of the circuit unit to be tested, but which are not themselves tested. The circuit unit 113 to be tested is supplied with a nominal data signal 117 via a data input unit 104.

Furthermore, in order to save one connector unit in the form of the data input unit 104, the nominal data signal 117 can also be supplied to the circuit unit 113 to be tested via the data bus 114 which is provided in the system interface 118. Furthermore the circuit arrangement 100 has a test mode input unit 102 for inputting a test mode signal 103.

As is illustrated in FIG. 1, the test mode signal 103 is supplied not only to the circuit unit 113 to be tested but also to a diversion unit 101. Supplying the test mode signal 103 to the circuit unit 113 to be tested means that a test mode, which can be specifically predetermined, is carried out as a function of the test mode signal 103 and of the nominal data signal 117 which is supplied via the data input unit 104 and/or via the data bus 114.

The circuit unit 113 to be tested emits an actual data signal 105, which is supplied via an internal data bus to the diversion unit 101. The circuit unit 113 to be tested and which, for example, is in the form of a memory module with DDR (double data rate) architecture, or architecture for double the data rate, furthermore has a synchronized signal production unit 107.

This synchronization signal production unit 107 emits a synchronization signal 106 which can be checked in the circuit units 113 to be tested and which are intended to be tested by means of the test apparatus and the test method according to the present invention. Conventional test apparatuses, as is shown in FIG. 2, have no diversion unit, so that the synchronization signal 106 must be emitted direct to a driver unit 108 and from it on to external units outside the circuit arrangement 100.

Thus, in the case of conventional test apparatuses and conventional test methods, parallelity for testing of circuit units to be tested is disadvantageously restricted.

According to the exemplary embodiment of the present invention shown in FIG. 1, it is now possible by means of the diversion device 101 to switch the synchronization signal 106 and to pass it to the driver unit 108 via a connecting device 111. It is thus possible to switch between the actual data signal 105 and the synchronization signal 106 by alternate switching in the diversion device, which is preferably in the form of an electronic changeover switch, for example comprising appropriately coupled AND gate units.

It should be mentioned that the diversion unit 101 may also be in the form of a mechanical changeover switch, provided that the switching process is carried out as a function of the test mode signal 103 which is supplied to the diversion unit 101. The signal which is driven/amplified in the driver unit 108 is, finally, supplied to a data output unit 109, which is used for emitting data from the circuit arrangement 100.

The data output unit 109 emits as an output signal a data output signal 110 which, according to the preferred exemplary embodiment of the present invention, is provided either by the actual data signal 105 (upper switch position in FIG. 1) or the synchronization signal 106 (lower switch position in FIG. 1).

The apparatus according to the invention thus makes it possible to test circuit units 113 to be tested which have a further signal 106 which, in the preferred exemplary embodiment according to the present invention, is in the form of a synchronization signal. No additional connecting pin is advantageously required for testing this further signal. The actual data signal 105 is tested in the conventional manner in the test apparatus, with the synchronization signal 106 being diverted by the diversion unit 101 once the actual data signal has been tested.

It should be mentioned that the actual mode signal 103 can furthermore be produced from data which is supplied via the system interface 118, that is to say via the data bus 114 and/or the address bus 115 and/or the control bus 116. This makes it possible to further reduce the number of pins (connecting pins) in the circuit arrangement 100 for connection of external circuit units to the test apparatus.

The following steps are now carried out in order to test a circuit unit 113 to be tested which has a synchronization signal production unit 107;
(i) the actual data signal 105 which is emitted from the circuit unit 113 to be tested is tested, in order to determine whether all of the data connecting units (data pins) are serviceable;
(ii) a test mode is carried out, during which the data pin is replaced by the DQS pin, that is to say the connecting pin for the synchronization signal; this allows the synchronization signal 106 to be checked and the serviceability of the synchronization signal production unit 107 to be tested; and
(iii) the test mode is deactivated and normal operation is resumed in accordance with step (i).

It should be mentioned that diversion of a further signal 106 is not restricted to a synchronization signal for the circuit unit 113 to be tested but that any desired additional signals which are emitted from the circuit unit 113 to be tested in addition to the actual data-signal 105 can be diverted to the drive unit 108 by means of the diversion unit 101.

Since the data output unit 109 now comprises only a single connecting pin in order to emit a data output signal 110, this makes it possible to increase the parallelity of the test method for testing circuit units 113 to be tested in a circuit arrangement 100. In the block diagram, as shown in FIG. 1, according to one preferred exemplary embodiment of the present invention, the synchronization signal production unit 107 in the circuit unit 113 to be tested is permanently connected to the diversion unit 101, with the synchronization signal 106 being supplied to the diversion unit 101 via a synchronization signal input connection.

However, average persons skilled in the art will be aware that any desired further signals which are emitted from the circuit unit 113 to be tested can be passed to the diversion unit 101 and/or to the synchronization input connection 112. Furthermore, the diversion unit 101 may have two or more changeover switches, such that two or more further signals 106 can be applied to the diversion unit 101 at the same time, thus making it possible to achieve further parallelity during the testing of circuit units to be tested.

With regard to the conventional test apparatus, which is illustrated in FIG. 2, for testing a circuit unit to be tested, reference should be made to the introduction to the description.

Although the present invention has been described above with reference to preferred exemplary embodiments, it is not restricted to them but can be modified in many ways.

In addition, the invention is not restricted to the cited application options.

List of Reference Symbols

Identical reference symbols denote identical or functionally identical components or steps in the figures.
100 Circuit arrangement
101 Diversion unit
102 Test mode input unit
103 Test mode signal
104 Data input unit
105 Actual data signal
106 Synchronization signal
107 Synchronization signal production unit
108 Driver unit
109 Data output unit
110 Data output signal
111 Connecting device
112 Synchronization signal input connection
113 Circuit unit to be tested
114 Data bus
115 Address bus
116 Control bus
117 Nominal data signal
118 System interface

1. Test apparatus for testing a circuit unit to be tested in a circuit arrangement, having:
a) a data input unit for supplying a nominal data signal to the circuit unit to be tested; and
b) a driver unit for driving the actual data signal (which is emitted from the circuit unit to be tested as a function of the nominal data signal supplied to it) to a data output unit, in which case the serviceability of the circuit unit to be tested can be determined by means of the actual data signal which is emitted to the data output unit,
wherein, the test apparatus furthermore has:
c) a diversion unit for diversion of at least one further signal, by means of which the serviceability of the circuit unit to be tested can further be determined, to the data output unit.

2. Apparatus according to claim 1, wherein the diversion unit is in the form of an electronic or mechanical changeover switch.

3. Apparatus according to claim 1 wherein the circuit arrangement has a test mode input unit, via which the diversion unit is supplied with a test mode signal.

4. Apparatus according to claim 1, wherein the circuit arrangement has a system interface which includes:
a) a data bus for interchanging data with the circuit unit to be tested;
b) an address bus for addressing data which is stored in the circuit unit to be tested; and
c) a control bus for controlling the interchange of data with the circuit unit to be tested.

5. Apparatus according to claim 1, wherein the circuit unit to be tested has a synchronization signal production unit, by means of which the further signal, with which the serviceability of the circuit unit to be tested can further be determined is produced.

6. Apparatus according to claim 5, wherein the further signal with which the serviceability of the circuit unit to be tested can be determined, and which is produced by a synchronization signal production unit for the circuit unit to be tested is a synchronization signal for the circuit unit to be tested.

7. Apparatus according to claim 1, wherein a connecting device is provided between the diversion unit and the driver unit, via which the actual data signal and the further signal are passed.

8. Method for testing a circuit unit to be tested in a circuit arrangement having the following steps:
a) supplying of a nominal data signal to the circuit unit to be tested via a data input unit;
b) supplying of the actual data signal which is emitted from the circuit unit to be tested as a function of the nominal data signal that is supplied, to a driver unit; and
c) driving the actual data signal which has been supplied to a data output unit by means of the driver unit with the serviceability of the circuit unit to be tested being determined by the actual data signal which is emitted to the data output unit,
wherein, the method furthermore has the following step:
d) diversion of an at least one further signal, by means of which the serviceability of the circuit unit to be tested can be further determined, to the data output unit by means of a diversion unit.

9. Method according to claim 8, wherein a test mode signal is produced for the diversion unit and is supplied to the circuit arrangements . . . a test mode input unit.

10. Method according to claim 8, wherein the further signal, by means of which the serviceability of the circuit unit to be tested is determined, is produced by means of a synchronization signal production unit (107) for the circuit unit 44 to be tested.

11. Method according to claim 10, wherein the further signal by means of which the serviceability of the circuit unit to be tested is determined, and which is produced by a synchronization signal production unit in the circuit unit to be tested, is in the form of a synchronization signal.

12. Method according to claim 8, wherein the actual data signal and the further signal are passed via a connecting device which is provided between the diversion unit and the driver unit.

13. Method according to claim 8, wherein the circuit unit to be tested is tested in accordance with a test mode which can be predetermined and which is supplied to the circuit arrangement as the test mode signal.

14. Method according to claim 8, wherein the diversion by means of the diversion unit is provided in accordance with the test mode which can be predetermined and is supplied to the circuit arrangement as a test mode signal.

15. Method according to claim 8, wherein the circuit unit to be tested is supplied with the nominal data signal via a data bus.
